(19) United States
(12) Patent Application Publication
(10) Pub. No.: US 2012/0161788 A1
(43) Pub. Date: Jun. 28, 2012

(54) MAGNETIC EFFECTS SENSOR, A RESISTOR AND METHOD OF IMPLEMENTING SAME

(75) Inventors: Joseph T. Siewick, McLean, VA (US); Frank Allen, McLean, VA (US)

(73) Assignee: Alion Science and Technology, McLean, VA (US)

(21) Appl. No.: 13/192,359

(22) Filed: Jul. 27, 2011

Related U.S. Application Data
(60) Provisional application No. 61/368,125, filed on Jul. 27, 2010.

(51) Int. Cl. G01R 27/26; H01C 7/13

(52) U.S. Cl. 324/654; 338/20

(57) ABSTRACT

A system of having a circuit having an electrical coil configured to generate a magnetic field based on properties of a surrounding space and an object presented to the electrical coil and a sensor configured to sense inductance and resistance of the electrical coil and to discriminate the object presented to the electrical coil in accordance with the sensing. A precision variable resistor to control resistance of an in-loop photoresistor with an out-loop photoresistor that are located parallel to each other.

### CROSS-REFERENCE TO RELATED APPLICATION

This application is related to and claims priority to U.S. Provisional Application Ser. No. 61/368,125, entitled MAGNETIC EFFECTS SENSOR, inventors Joseph T. Siewick, et al., filed Jul. 27, 2010, in the United States Patent and Trademark Office, the disclosure of which are incorporated herein by reference.

### BACKGROUND

1. Field

The embodiments discussed herein are directed to a magnetic effects sensor, a resistor and a method of implementing same.

2. Description of the Related Art

Generally, in existing sensing technologies such as induction sensing a finite conductance (to support an eddy current) is essential. The finite conductance requirement presents a problem in induction sensing and other similar sensors because in some situations, conductive nature (conductive metal content) is decreased to the point where there are no currents to sense. For example, dry sand (or other similar medium) is particularly challenging for induction sensing because the eddy current signal contrast from the void created by an implanted, plastic case mine may near zero to where the plastic mine looks like non-conductive sand. Further, sensing of objects that do not have metal content may be necessary.

Attempts have been made to improve range of sensing. However, range of existing sensing including that of induction sensing is limited.

Although various types of sensor technologies are available, there is a need for a sensor technology that is enabled to detect objects and addresses problems associated with existing sensing technologies including induction sensing.

### SUMMARY

It is an aspect of the embodiments discussed herein to provide a sensor and method thereof for sensing an object possessing magnetic and conductive properties including based on how the object influences an impedance of a magnetic coil and a circuit that includes the coil.

The above aspects can be attained by a system having an adjustable precision variable resistor that can be under automatic control to maintain or stabilize a bridge circuit against resistive drifts away from null.

These together with other aspects and advantages which will be subsequently apparent, reside in the details of construction and operation as more fully hereinafter described and claimed, reference being had to the accompanying drawings forming a part hereof, wherein like numerals refer to like parts throughout.

### BRIEF DESCRIPTION OF THE DRAWINGS

FIG. 1 illustrates an exemplary AC Source, Capacitor and Resistor series circuit and voltage signal relationships.

FIG. 2 illustrates an exemplary AC Source, Resistor and Coil series circuit and voltage signal relationships.

FIG. 3 illustrates an exemplary three-Arm Reactance Bridge Diagram of a magnetic effects sensor (MES) Sensor.

FIG. 4 illustrates an exemplary MES Reference and Measurement Signals Phase-Amplitude Relationship.

FIGS. 5A, 5B and 5C illustrate exemplary bridge circuits.

FIG. 6 illustrates an embodiment of a bride circuit with geometric representation of voltage drop phases and amplitudes at Null.

FIG. 7 illustrates an embodiment of geometric representation of the quadrature (left) and phase (right) bridge signals.

FIG. 8 illustrates an embodiment of a method and means for determining In-Phase and Quadrature amplitudes.

FIG. 9 illustrates an embodiment of an optical nulling method and means.

FIG. 10 illustrates an amplitude comparison (simple sorting) discrimination algorithm.

FIG. 11 illustrates an embodiment of notional magnetic effects sensor system.

FIG. 12 illustrates an exemplary a magnetic bridge circuit.

FIG. 13 illustrates a process for sensing an object.

### DETAILED DESCRIPTION OF THE EMBODIMENTS

Reference will now be made in detail to the present embodiments discussed herein, examples of which are illustrated in the accompanying drawings, wherein like reference numerals refer to the like elements throughout. The embodiments are described below to explain the disclosed system and method by referring to the figures. It will nevertheless be understood that no limitation of the scope is thereby intended, such alterations and further modifications in the illustrated device, and such further applications of the principles as illustrated therein being contemplated as would normally occur to one skilled in the art to which the embodiments relate.

The embodiments have been described with respect to a magnetic effects sensor and method of implementing same.

Magnetic effects sensor (MES) is new sensor technology; and is different from an induction sensor. The heart of the MES is a passive reactance bridge whose response is influenced by the electrical-magnetic properties of the medium permeated by magnetic field of its coil. A finite conductance (to support an eddy current) is essential for induction sensing, but it is not essential to the MES. This finite conductance requirement is the weakness in induction sensing because the (conductive) metal content of landmines, for example, is decreasing to where there are no eddy currents to sense. For example, dry sand (like in Iraq) is particularly challenging for induction sensing because the eddy current signal contrast from the void created by the implanted, plastic case mine nears zero to where the plastic mine looks like non-conductive sand. The information produced by the MES is very different from that of an induction sensor; and it has detected plastics and nonconductive ceramics from their permeability (magnetic polarizability) which materials are undetectable with an induction sensor.

The MES exploits the fact that the resistance and inductance of an electrical coil depends on the properties of the surrounding space that are permeated by the magnetic flux from the coil. A nulled, AC reactance bridge circuit (incorporating a coil) provides the best known way to exploit this impedance dependence to sense and discriminate objects presented to the coil from the bridge imbalance signal.

As is set forth herein, one advantage provided by this new sensor over existing magnetic sensors is its ability to cancel out ambient magnetic effect clutter in the bridge nulling procedure, which helps us discriminate the occulted objects of interest. Additionally, the circuit provides signals and signal references that allow us to separate the change in coil resistance from the change in coil inductance as a function of frequency. The increase in coil resistance is caused by resistive losses of the eddy currents induced in permeated objects. The change in inductance is caused by induced magnetic polarization in permeated objects and the attendant diamagnetic field of any eddy current in conductive objects. The resistive and inductive signals as a function of frequency are used to discriminate sought objects presented to the coil.

According to an embodiment, the MES detects and discriminates occulted objects including in close proximity to the sensor. Exploiting the complexity of magnetic effects data with various signal filtering alternatives, the MES can be used as a cueing/discrimination sensor for buried targets, or as a discrimination sensor for suspicious targets above ground. For example, the MES can detect and discriminate landmines, artillery shells, improvised explosive devices (IEDs), and bulk explosives of various chemical compositions that are devised by our adversaries.

Generally, a magnetic coil is a continuous electrically insulated wire or other suitable conductive material that is looped partially and, or completely a number of times around an axis. A magnetic field is caused when electrical current passes through such a coil in accordance with the applicable physics. Applicable physics also describes how a magnetic coil converts electrical energy to magnetic energy which energy is stored in the magnetic field of the coil and dissipated by magnetically-induced eddy currents in conductive materials.

Magnetic fields permeate the medium surrounding the source magnetic dipole and an attractive or repulsive force may result depending upon whether there is a net reduction or increase in energy because of it. A magnetic coil with an applied DC current may create a similar magnetic field with the same repulsive and attractive effects. However, the magnetic coil also features an electrical impedance; and this impedance is influenced by the media the magnetic field passes through. Therefore, according to an embodiment, it is possible to sense a remote object possessing magnetic and conductive properties by understanding and exploiting how the object influences the impedance of a magnetic coil and the circuit that includes the coil.

The behavior of a transformer, under the influence of an alternating current, is instructive to understanding the basic concepts of magnetic sensing through the agency of a magnetic coil. A transformer is two electrically distinct coils arranged to optimize the transfer of alternating current (AC) electrical power (with minimal loss) between the coils. Since energy is conserved in the ideal transformer, the power into the primary coil of such a transformer is equal to the power output by the secondary coil of the transformer. Typically, the impedance of electrical components connected to complete a circuit including the secondary coil of the transformer affect the impedance of the primary coil of the transformer. Thus, the resistive, capacitive and inductive properties of components contained in a circuit including the secondary coil of the transformer may be determined by measuring the impedance of the primary coil and performing an appropriate analysis.

An alternating magnetic field, caused by a sinusoidal current passing through a magnetic coil, causes several effects in materials permeated by the magnetic field. Sinusoidal magnetic fields induce eddy currents in conductive materials permeated by the magnetic field. Magnetic fields alter the magnetic polarization of ferromagnetic materials and induce magnetic polarization in magnetically susceptible materials. If the magnetic field is sinusoidal, these effects will sympathetically follow the sinusoidal influence of the causal magnetic field at low frequencies up to a frequency (unique to each effect) above which each effect begins to diminish due to a finite response.

Remote eddy currents induced by the AC magnetic field of the coil increase the resistance of the coil. Remote magnetic polarization of material by the influence of the AC magnetic field of the coil affects the inductance of the coil. The diamagnetic or paramagnetic qualities of the medium, and objects permeated by the magnetic field, cause a decrease or increase in the inductance of the coil. These resistive and inductive effects in the coil are sensible by the way the coil affects a circuit to which it is connected as a functional component.

According to an embodiment an optimal sensing coil circuit is provided to enable distinct outputs inferential of the magnetic and resistive properties of media and objects permeated by the magnetic field of the coil. Generally, any circuit containing a coil may be used to implement the present invention. Extensive study and testing of various circuits suggests that a bridge circuit containing a coil provides optimal performance. The Owens bridge, the Hay bridge and the Maxwell-Wien bridge are typical impedance bridges and all three are suitable for inductance sensing.

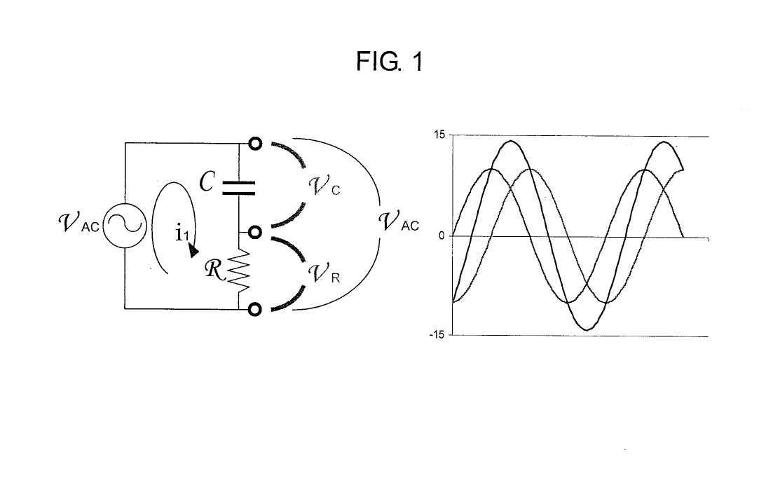

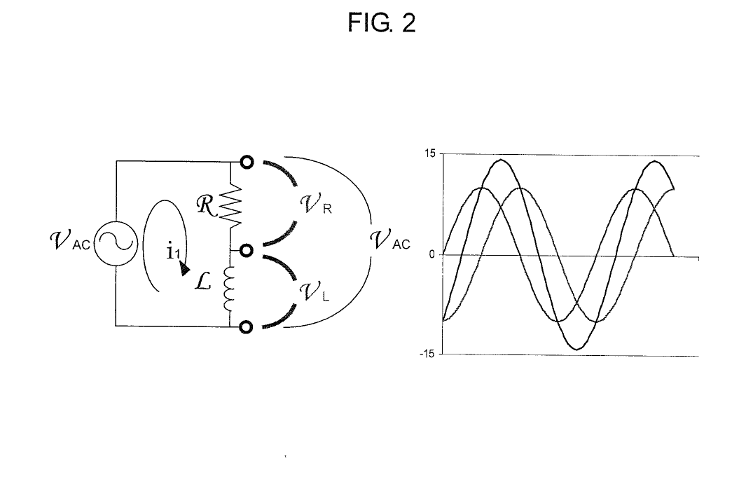

FIGS. 1 and 2 illustrate the way the voltage signals across a capacitor and coil are related to the voltage signal across a resistor in series with said capacitor or said inductor. While the phases in each case differ by ninety degrees in phase, the sum of the voltages across the components in each series circuit equals the applied AC voltage all the time. In particular, it should be noticed that were the two circuits connected in parallel so they shared a common AC voltage supply, the voltage across the capacitor, C, of FIG. 1 shares phase with the resistor, R, of FIG. 2 and the voltage across the coil, L, of FIG. 2 shares phase with the resistor, R, of FIG. 1.

A useful bridge circuit for magnetic sensing with a coil takes advantage of such phase and voltage relationships illustrated in FIGS. 1 and 2 to provide a two-arm bridge circuit which may be balanced in that the almost-zero AC voltage signal will be produced between two electrically uniform distinct locations (or points) in the nulled circuit when a much larger amplitude voltage AC signal is applied across the bridge.

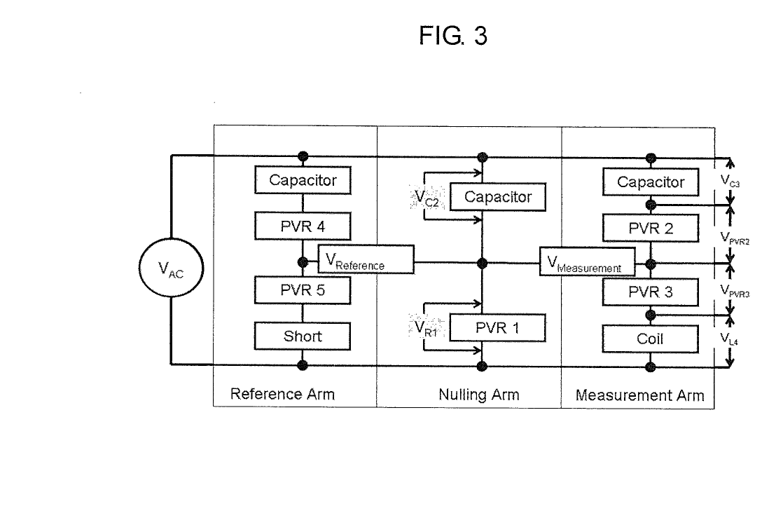

FIG. 3 illustrates an exemplary 3-Arm Reactance Bridge Diagram of the MES. Sensor. According to an embodiment, the MES operates more like an analytical instrument than a sensor; as it separately determines the inductive and resistive components of the response signal and quantifies these against a reference standard. As depicted in FIG. 3, the MES includes three arms comprising a reactance bridge with a Nulling Arm, a Reference Arm and a Measurement Arm. The Nulling Arm provides a signal ground for the reference and measurement arms that produce their signals. The Reference Arm produces the signals of a perfect diamagnetic zero-resistance object similar to what a superconductor would produce were it installed filling the inside of the measurement arm. Zero inductance and zero resistance are a unique zero-zero point at the axis intersection of the reactance plot. The Measurement Arm produces signals from the ground and objects contained within the ground. The MES uses the zero-zero reference arm signals to decompose the measurement arm signals into an in-phase (inductance) and quadrature (resistance) component at each sweet spot frequency where perfect orthogonality of the in-phase and quadrature reference signals is possible.

As shown in FIG. 3, the MES Sensor, includes PVR components 1, 2, 3, 4 and 5 which are provided to the Nulling Arm, the Reference Arm and the Measurement Arm. According to an embodiment, the PVR components, depicted in FIG. 3, may be precision variable resistors which are proprietary to Alion Science and Technology. For example, the PVR components are settable under computer control to any resistance within an adjustment range to 20 bit accuracy and the resistance holds to its set point with about 100 parts per million precision against resistance drifts. These PVRs settle to their set points in under one second and make possible a simple nulling procedure that is a key ingredient of the MES technology described herein. While a specific adjustment range is described herein, the present invention is not limited to any particular adjustment range.

As shown in FIG. 3, according to an embodiment of a magnetic effects sensor, arms of the sensor are populated with precision variable resistors (PVRs). These are configured to be tuned by the operator to a specific resistance, and they are designed to hold that resistance through a software feedback loop, for example. In the MES, the resistances are adjustable, known values. The resistors may be within a control loop (in loop) that includes a digital/analog and analog/digital converter and a microprocessor, or outside the control loop (out-loop). According to an embodiment, a system may include a converter configured to selectively convert information of a measured resistance due to a voltage drop pertaining to a current source, a microprocessor receiving information of the measured resistance and a controller to sympathetic control resistance of an in-loop photoresistor with an out-loop photoresistor that are located parallel to each other.

According to an embodiment of the sensor, capacitors are carefully chosen to be precisely matched in each of the various arms of the sensor (FIG. 3). The capacitances are fixed, known values. The MES has to be engineered to minimize the effects of stray capacitance on the impedance of the circuit. In the Magnetic Effects Sensor of an embodiment, the sensor is designed to operate over a range of AC frequencies. The frequency range is chosen by the designer, based upon the AC frequency range of interest. These frequencies will impact the impedance of the MES circuit, and MES has to be designed to account for these AC frequency effects. In the MES, the AC frequencies are adjustable, known values.

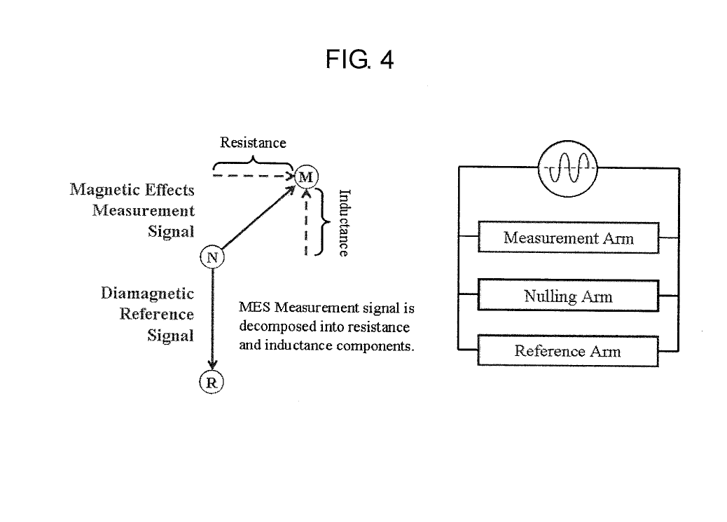

FIG. 4 shows and example relationship between the MES Reference and Measurement Signals. The amplitude of the in-phase Reference Signal is precisely that produced by the inductance of the isolated sense coil; and that precision makes possible the quantification of the measurement signals relative to that coil inductance.

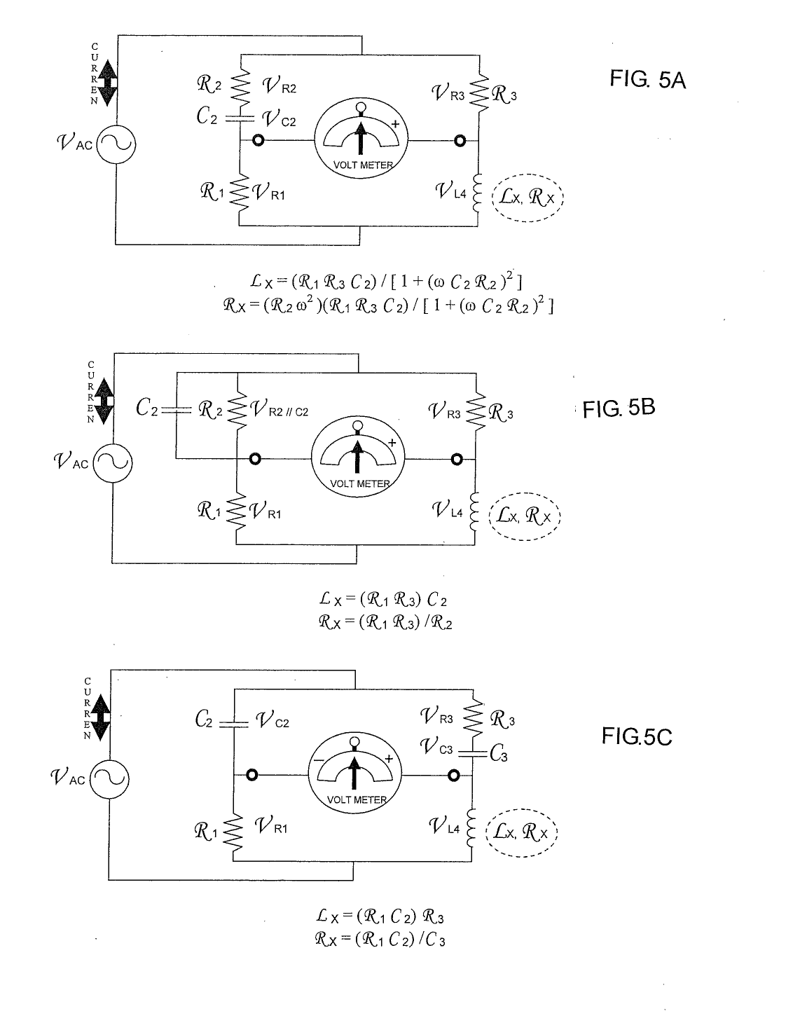

FIGS. 5A, 5B and 5C illustrate exemplary bridge circuits. Generally, the Hay, Maxwell-Wien, and Owens bridges are often used to make precise laboratory measurements of inductance. According to an embodiment, any one of these bridges are suitable for sensing slight inductance and resistance changes in a coil. Generally, the Hay bridge may be less suitable for such use as a sensor because it must be readjusted for balance as the AC frequency changes. The Maxwell-Wien and Owens bridges are better choices for a magnetic effects sensor because they generally maintain balance over a range of frequencies. The Owens bridge has a further advantage over the Maxwell-Wien in that the principal adjustment components for balance is in series with the sensing magnetic coil allowing the voltage drops across the R₁ and C₂ components of the alternate series circuit to be available as reference signals useful for further signal processing of the bridge imbalance signal.

FIGS. 5A, 5B and 5C illustrate the hay bridge circuit, the Maxwell-Wien bridge circuit and the Owens bridge circuit, respectively. With respect to FIG. 5C, a typical Owen Bridge is an AC bridge circuit that is useful for measuring an unknown inductance by balancing the loads of its arms, one of which contains the unknown inductance. The inductance measuring ability of the Owen Bridge can only be realized when the circuit is balanced by, for example, adjusting an arm of the bridge circuit until the current through the bridge between points A and B becomes zero. However, the balancing of an Owen Bridge is independent of AC frequency. As is explained herein, the sensor of the present invention is configured to operate over (and remain balanced over) a wide range of AC frequencies. According to an embodiment, specific resistive and inductive responses of the sense coil may occur at specific AC frequencies that imbalance a bridge circuit, depending on what is contained in the area of interest, and these specific responses are markers to a peculiar threat object, or class of objects, hidden in the area of interest.

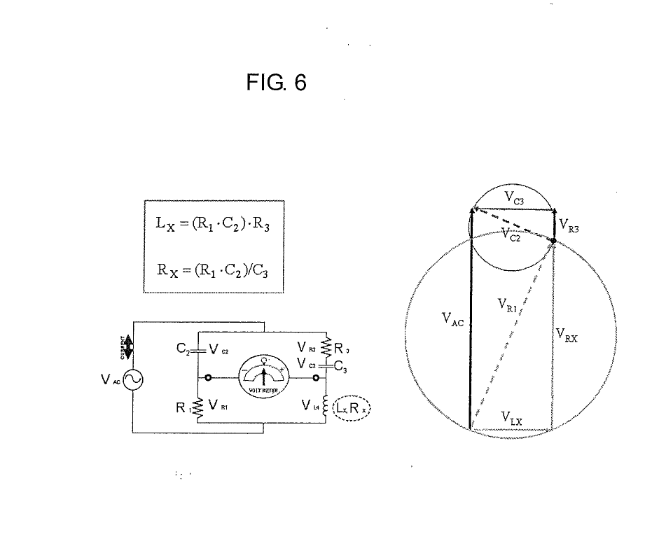

FIG. 6 illustrates a bride circuit with geometric representation of voltage drop phases and amplitudes at Null. As shown in FIG. 6, the Owens bridge circuit is used to illustrate a magnetic effects sensor according to an embodiment. To better understand the operations of the magnetic effects sensor, it may be best to refer to voltage signals depicted in FIGS. 1 and 2 as associated with the identifiably similar AC source-component, sub-circuits of FIG. 5C. At perfect balance (shown in FIG. 6), the voltage between the said electrical points (connected through the voltmeter, shown) is precisely zero because the phase and amplitude of voltage V_{R1} equals that of V_{L4}. This voltage balance is achieved when the L_{X} and R_{X} of the coil equal (R₁C₂) R₃ and (R₁C₂)/C₃ computed from the values of other components shown in the bridge circuit. Hereinafter L_{X} and R_{X} are the quiescent inductance and quiescent resistance of the balanced coil. The resistor, R₃, is adjustable by intentional influence over a range of resistance values needed to balance the bridge to the quiescent inductance of the coil. The capacitor, C₃, is adjustable by intentional influence over a range of capacitance values needed to balance the bridge to the quiescent resistance of the coil. Once balanced for the local environment, the bridge circuit is unbalanced when the component values fail to compute to the perturbed inductance, L_{X}±I_{X} and, or perturbed resistance, R_{X}+r_{X}, where I_{X} and r_{X} are additional inductance and resistance caused by the influence of susceptible and inductive materials. The components R₃ and C₃ have additional usefulness in that they provide reference voltages for separating the in-phase and quadrature bridge response signals caused by an imbalance.

When the Owens Bridge is nulled, the triangles in FIG. 6 are all similar and rotated relative to one another. The relevant linear algebra comporting with geometry and circuit analysis is as follows.

$$\begin{matrix}( \begin{matrix}{V}_{LX} \\ {V}_{RX}\end{matrix} ) = ( \begin{matrix}jω \cdot {L}_{X} \\ {R}_{X}\end{matrix} ) \cdot i ( ω ) \\ = ( \begin{matrix}0 & {R}_{1} \cdot jω \cdot {C}_{2} \\ {R}_{1} \cdot jω \cdot {C}_{2} & 0\end{matrix} ) \cdot ( \begin{matrix}1 / ( jω \cdot {C}_{3} ) \\ {R}_{3}\end{matrix} ) \cdot i ( ω )\end{matrix}$$

$$Similar Triangles \text{:} \frac{\vert {{V}^{->}}_{LX} \vert}{\vert {{V}^{->}}_{RX} \vert} = \frac{\vert {{V}^{->}}_{R 3} \vert}{\vert {{V}^{->}}_{C 3} \vert} = \frac{\vert {{V}^{->}}_{R 1} \vert}{\vert {{V}^{->}}_{C 2} \vert} and \begin{matrix}{{V}^{->}}_{LX} \vert \vert {{V}^{->}}_{C 3} \\ {{V}^{->}}_{RX} \vert \vert {{V}^{->}}_{R 3}\end{matrix}$$

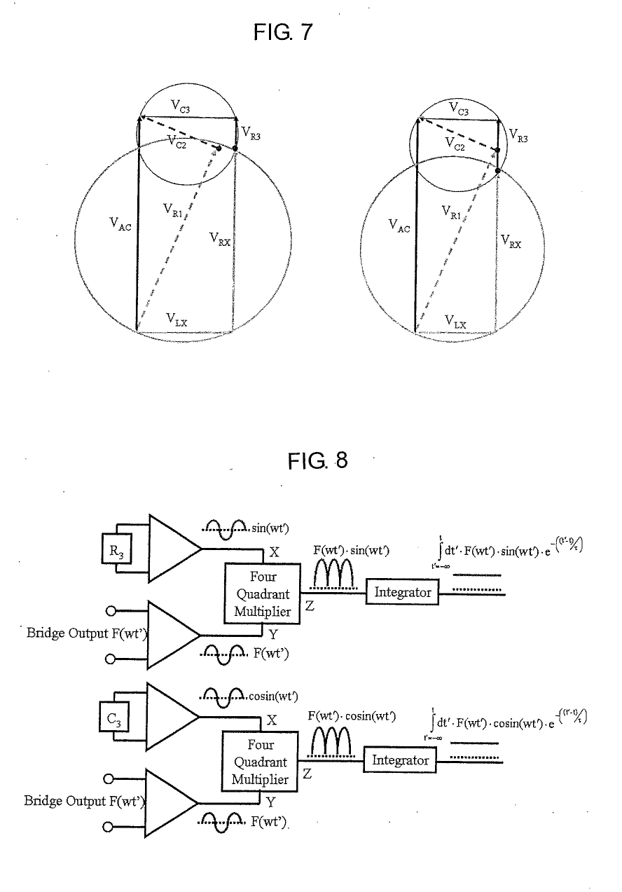

The AC resistance of the coil is altered from its quiescent value, R_{X}, to a perturbed value, R_{X}+r_{X}, at frequencies below the response frequency of the inducible eddy currents, by power loss to said eddy currents induced in conductive materials permeated by the AC field of the coil. The imbalance (Shown in the right side of FIG. 7) will appear as if it were a change in the amplitude of the voltage across the resister of FIG. 2.

The AC inductance of the coil is altered from its quiescent value, L_{X}, to a perturbed value, L_{X}±l_{X}, at frequencies below the response frequency of the magnetically susceptible materials, by increased or decreased energy storage in the magnetic polarization of susceptible materials permeated by the AC field of the coil. In diamagnetic materials the material polarization opposes the field with a net reduction in energy storage and an attendant reduction in the inductance of the coil. In paramagnetic materials the material polarization enhances the field with a net increase in energy storage and an attendant increase in the inductance of the coil. The imbalance (Shown in the left side of FIG. 7) will appear as if it were a change in the amplitude of the voltage across the inductor of FIG. 2.

FIG. 7 illustrates an embodiment of geometric representation of the quadrature (left) and phase (right) bridge signals. The general case imbalance will produce AC signals due to both susceptibility (inductance) and eddy current (resistance) effects caused by the materials permeated by the magnetic field of the coil. The voltage signals due to these imbalance effects may be distinguished from each other by matched filtering using the voltage signals across R₃ and C₃ as a reference in-phase signal and a reference quadrature signal.

FIG. 8 illustrates an embodiment of a method and means for determining In-Phase and Quadrature amplitudes. As shown in FIG. 8, the method determines the in-phase and quadrature signal amplitudes by mixing the sinusoidal bridge signal with the sine and cosine components across R₃ and C₃ to produce the time-integrated products. The analog circuit to do this involves four quadrant multiplier ICs and Op-amp integrators. The basic circuits and associated signal processing arithmetic are shown in FIG. 8.

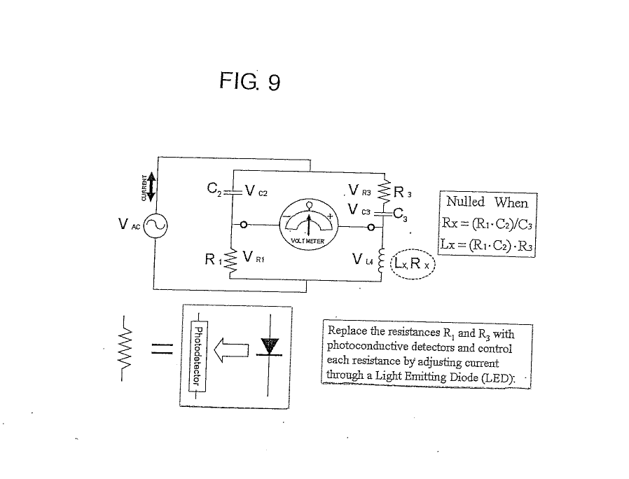

FIG. 9 illustrates an embodiment of an optical nulling method and means. As explained relative to FIG. 9, a sensor according to an embodiment includes an ability to null out ambient magnetic effect clutter, which for example helps to discriminate the occulted objects of interest. The null equations for the Owens Bridge (shown in FIG. 9) do not depend on the AC frequency which means that the component values for null are the same at any AC frequency over the operating range of the Owens Bridge, for example. Additionally, the circuit provides complex signals and signal references that enables separation of a change in coil resistance from a change in coil inductance as a function of frequency. The resistive and inductive signals as a function of frequency are used to discriminate sought objects presented to the coil.

A new method and means for rapidly and adaptively nulling the bridge shown in FIG. 9 enables a key feature in discriminating objects. For example, other components used in the Army's HSTAMIDS mine sensor cause their own magnetic effects that present clutter against which a sought landmine must be sensed. The Owens Bridge may be adjusted by optical means to null out the clutter from these other components and the ground clutter; leaving only the signals from a possible landmine or other interesting objects. Nulling the ground and other uninteresting signals doesn't affect the signals from the magnetic effects of a mine and other interesting objects.

This optical nulling technique is easily automated with a simple bisection algorithm. The optical control is determined during a test sensing procedure to automatically null the bridge for the ambient static or temporal clutter in the absence of a sought object. An example of temporal clutter is the periodic clutter presented by placing the sensor on a moving (rolling variable wheels) vehicle. An example of static clutter is that presented by the ground occulting a buried landmine.

Generally, the signals produced by the magnetic effects sensor are complex and information rich. This complexity affords the opportunity to use several filtering methods to process the signals for their information. From Linear Algebra it is known that the number of sought objects discriminated, N, requires the same number of distinct parameters. These parameters are the in-phase and quadrature amplitudes of the bridge response signal at each distinguishable signal frequency applied to the bridge.

Matched filtering and novelty filtering are two methods that offer superior performance for myriad magnetic effect sensing applications. A filter is the sum of products of the weighted mean-removed signal, Sᵢ, and target template, Tᵢ, generally represented mathematically as

$$F = {\sum }_{i = 1}^{N} {W}_{i} \cdot {T}_{i} \cdot {S}_{i} where \{ \begin{matrix}{T}_{i} = {t}_{i} - \overline{t} & \overline{t} = {\sum }_{i = 1}^{N} {t}_{i} / N \\ {S}_{i} = {s}_{i} - \overline{s} & \overline{s} = {\sum }_{i = 1}^{N} {s}_{i} / N\end{matrix}$$

The numerical weight, Wᵢ, increases proportional to the significance attributed to the products. For Optimal Matched Filtering the weight scales inversely with signal noise and clutter. Matched Filtering produces an output that is proportional to the degree of similarity of the signals to a template. Each sought target template is a distinct channel output for this filter. The following plot shows the matched (red) and unmatched (blue) filter output.

For Novelty Filtering, the calibrated mean-removed clutter signal is the template, the mean-removed sensed clutter is the signal and the deviation of the product output from one is proportional to the novelty from calibrated clutter. Statistically significant deviations from the calibrated clutter may indicate interesting signals telling of novelty.

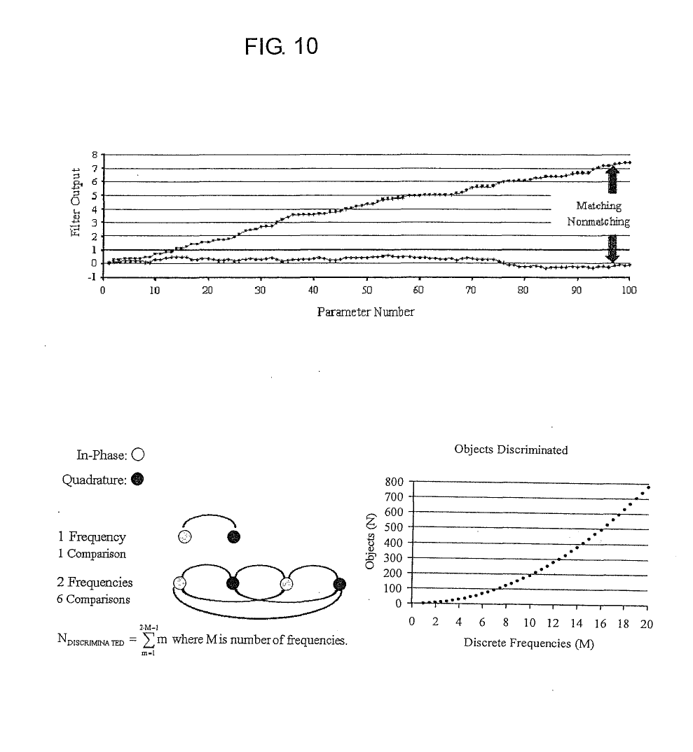

Simple comparisons provide a fast (though sub-optimal) Matched Filter algorithm that lends itself to phase and quadrature amplitude comparison at AC frequencies. FIG. 10 shows how the number of uniquely discriminated sought signals depends on the number of comparable signal parameters.

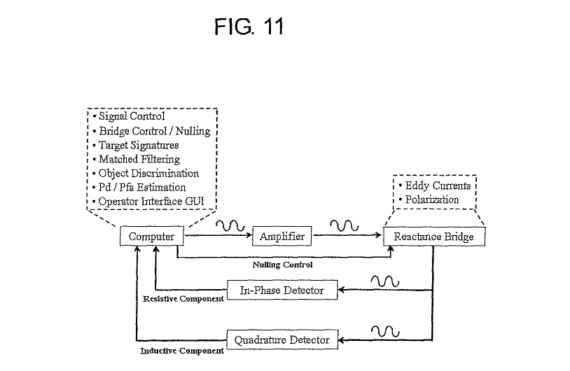

FIG. 11 illustrates an embodiment of notional magnetic effects sensor system. As shown in FIG. 11, the system includes a computer, an amplifier, a nulling control, an in-phase detector, a reactance bridge, a quadrature detector, and a resistive and inductive component. Accordingly, the sensor system of an embodiment separates a change in coil resistance from a change in coil inductance as a function of frequency. The increase in coil resistance may be caused by resistive losses of the eddy currents induced in permeated objects and a change in inductance may be caused by induced magnetic polarization in permeated objects. The resistive and inductive signals as a function of frequency are used to discriminate sought objects presented to the coil.

As shown in FIG. 11, the system may include a computer which may be implemented via one or more processors, a specialized system or other general purpose device that allows a process to be implemented with respect to sensed information.

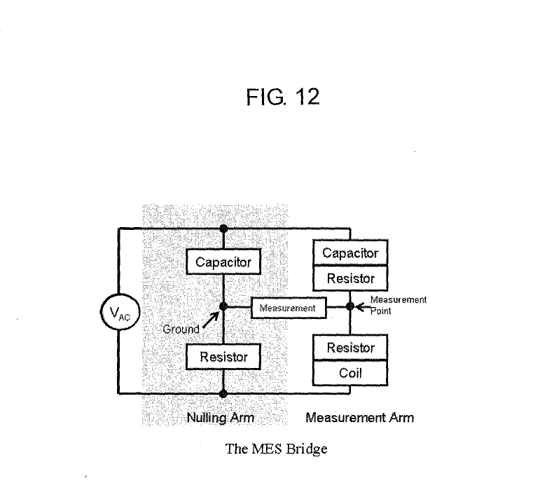

FIG. 12 illustrates a magnetic bridge circuit. As shown in FIG. 12, the circuit includes a Nulling Arm (the balancing arm) and a Measurement Arm. The adjustments to be made according to an embodiment are to achieve the null condition (balancing the bridge) are entirely in the Measurement Arm and the nulling condition is independent of AC frequency. This means that the MES can step through a range of sensing frequencies without having to be nulled each time at each frequency. An offset from perfect null can be handled as either signal clutter if it is correlated with the sensing frequency, or suppressed with Coherent Processing as noise if it is erratic during the signal processing integration period MES uses capacitors having nearly identical capacitance in the Nulling and Measurement Arms. The MES uses Precision Variable Resistors in the two arms. MES is easily and automatically nulled at the L-C resonance frequency of the coil and capacitor in the Measurement Arm by adjusting the three Precision Variable Resistors to have the same resistance that is equal to the identical reactance of the two capacitors and coil at the L-C resonance frequency.

According to an embodiment, the sensor capitalizes on many of the sensing nuances and engineering possibilities. For example, the system of the present invention detects phase behavior such as an AC voltage drop occurs across a component as a consequence of the AC current flowing through that component including, the sine wave phase of the AC voltage drop across a resistor shares phase with the sine wave AC current flowing through that resistor, the The sine wave phase of the AC voltage drop across a capacitor depends on the accumulation of charge on the electrodes and lags behind, by ninety degrees, the sine wave AC phase of the current flowing through that capacitor, and the sine wave phase of the AC voltage drop across a coil depends on the magnetic field produced by the coil and leads, by ninety degrees, the sine wave AC phase of the current flowing through that coil.

The nulling (balancing) the bridge circuit is implemented where the current flowing in each arm of the bridge is the same current at the same phase through each series component in each arm. This means that the voltage drops across each of the components is produced to cause a voltage drop between two measurement points, one point each in each arm. This voltage drop is called the Bridge Signal.

The Bridge Signal may be nulled (meaning it has a zero AC voltage drop when the bridge is nulled) and may have an AC voltage amplitude at some phase relative to that of the AC Bridge Excitation Signal when the bridge is imbalanced. Nulling the bridge is easier at the resonant frequency of the capacitor and coil in the measurement arm of the bridge. Nulling the bridge becomes practical and straight-forward if the capacitors have the same capacitance. This is because the AC voltage drops at that frequency across each component in any arm are all equal in voltage at null.

The bridge resistors can be replaced by a photoconductive photocell under optical control to provide an adjustable Precision Variable Resistor (PVR) that can be under automatic control. The benefit of a Precision Variable Resistor is they stabilize the bridge against resistive drifts away from null.

According to an embodiment, an automated adjustment of the PVRs is provided to null the bridge with the highest precision without measuring AC voltage drops across the bridge components. This is done by using the fact that, when the phase of the Reference Signal is set to be 45 degrees relative to that of the Bridge Excitation Signal at the L-C resonance frequency, the changes in the Bridge Signal caused by changing the resistance of the two PVRs are independent of each other and are perfectly aligned with the In-phase and Quadrature components produced by Coherent Processing. Under this set of amazing relationships, the bridge is nulled by simply setting the In-phase signal to zero by adjusting one PVR and adjusting the Quadrature signal to zero by adjusting the other PVR. This allows us to avoid conducting AC voltage drop measurements, which would draw current and negatively impact our nulling precision.

Dealing with Parasitics. An Owen Bridge, constructed of ideal components, remains nulled at all bridge AC excitation frequencies. A frequency-dependent correction may be applied to the output signal of the nulled bridge because of the parasitic impedances of imperfect bridge components. In an embodiment, the necessary offset correction may be minimized by engineering improved bridge components with minimal parasitics.

Signal response association to threat objects. The inductance of the coil will vary from its value used to null the bridge proportionate to the paramagnetic and diamagnetic properties of objects placed in the AC field of the coil. These properties imbalance the bridge. In an embodiment, paramagnetic and diamagnetic influences may be associated to a particular threat object.

The resistance of a component is equal to the ratio of power dissipated by that component and the current flowing through it. An electrical coil has an AC resistance that can be different from the DC resistance that may be measured with a voltmeter. The MES exploits the AC coil resistance caused by a power loss from the AC magnetic field of the coil to objects in that field that absorb and dissipate that power. This imbalances the bridge, and may provide valuable clues to a threat object.

The imbalance signal of the bridge for a change in the coil inductance is electrically-distinguishable from the imbalance signal for a change in the coil resistance. This capability may be exploited to help us identify a threat object.

Advanced Signal Processing. The fact that the AC Bridge Signal has the same frequency as the AC Bridge Excitation Signal means that Coherent Processing, with a Reference Signal that is derived from the Bridge Excitation Signal, may be used to process the Bridge Signals to achieve the very high sensitivity that is possible with other techniques such as laser interferometry. The Coherent Processing can distinguish phase differences between the Bridge Signal and the Reference Signal into two AC components that sum to the Bridge Signal. These components as the In-phase and Quadrature components.

The In-phase component has the same AC phase as the Reference Signal. The Quadrature component has an AC phase that is shifted ninety degrees in phase away from the AC phase of the Reference Signal. Sensing performance over a range of AC frequencies. At the L-C resonance frequency, the nulling point in the Nulling Arm is midway between the maximum and minimum AC Excitation Voltage. The nulling point moves to minimize the linear bridge imbalance signal range for a change in coil impedance and the effects of parasitic impedances become increasingly pronounced with increasing or decreasing frequency away from the L-C resonance frequency where the best null was achieved. Good sensing performance can be expected with the MES over a range of frequencies from a half resonant frequency to twice resonant frequency of the sensor.

According to an embodiment, a magnetic effects sensor can be deployed as either a hand-held or vehicle mounted sensor for detecting buried/hidden objects of interest. It can also be applied to many other sensing requirements in private industry. It can be engineered into an extremely small form factor, with flea-power energy requirements. Unlike an induction sensor or other similar sensors, the disclosed sensor can detect objects including those that have absolutely no metal components. Unlike an induction sensor, the MES does not send out an active signal.

The idea behind the MES is to produce a very sensitive device that measures changes to the resistance and inductance of the sensing coil, across an AC frequency range. These changes to the sensing coil are responses induced by the interaction of the coil with an area of interest. Across the AC frequency range, at each step frequency, the MES detects both the resistance and the inductance changes—independently of each other. The MES components are selected with a particular frequency range in mind—selected based upon some knowledge of the targets of interest. This information can be exploited for target discrimination.

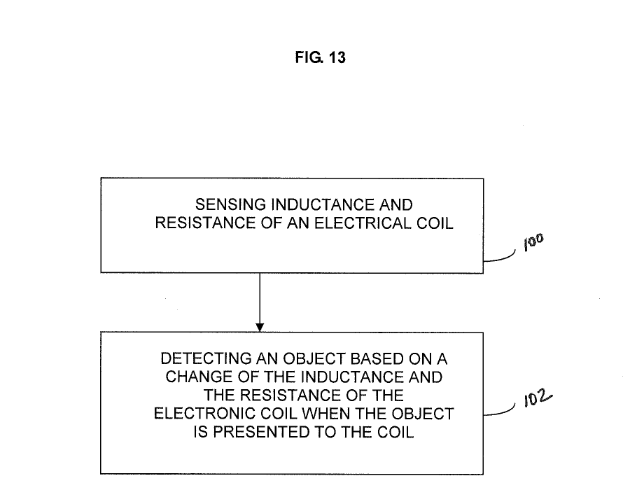

FIG. 13 illustrates a process for sensing an object. As shown in FIG. 13, the process begins by sensing, using a magnetic effects sensor for example, inductance and resistance of an electrical coil. After sensing 100, the process moves to detecting 102 an object based on a change of the inductance and the resistance of the electronic coil when the object is presented to the electronic coil.

The embodiments can be implemented in computing hardware (computing apparatus) and/or software, such as (in a non-limiting example) any computer that can store, retrieve, process and/or output data and/or communicate with other computers. The results produced can be displayed on a display of the computing hardware. A program/software implementing the embodiments may be recorded on computer-readable media comprising computer-readable recording media. The program/software implementing the embodiments may also be transmitted over transmission communication media. Examples of the computer-readable recording media include a magnetic recording apparatus, an optical disk, a magneto-optical disk, and/or a semiconductor memory (for example, RAM, ROM, etc.). Examples of the magnetic recording apparatus include a hard disk device (HDD), a flexible disk (FD), and a magnetic tape (MT). Examples of the optical disk include a DVD (Digital Versatile Disc), a DVD-RAM, a CD-ROM (Compact Disc-Read Only Memory), and a CD-R (Recordable)/RW. An example of communication media includes a carrier-wave signal.

Further, according to an aspect of the embodiments, any combinations of the described features, functions and/or operations can be provided.

The many features and advantages of the embodiments are apparent from the detailed specification and, thus, it is intended by the appended claims to cover all such features and advantages of the embodiments that fall within the true spirit and scope thereof. Further, since numerous modifications and changes will readily occur to those skilled in the art, it is not desired to limit the inventive embodiments to the exact construction and operation illustrated and described, and accordingly all suitable modifications and equivalents may be resorted to, falling within the scope thereof.

What is claimed is:

1. A magnetic effects sensor, comprising:
a circuit having an electrical coil configured to generate a magnetic field based on properties of a surrounding space and an object presented to the electrical coil; and
a sensor configured to sense inductance and resistance of the electrical coil and to discriminate the object presented to the electrical coil in accordance with the sensing.

2. The magnetic effects sensor according to claim 1, wherein the circuit provides signals and signal references to determine a change in coil resistance and a change in coil inductance as a function of frequency.

3. The magnetic effects sensor according to claim 1, wherein ambient magnetic effect clutter is cancelled out to discriminate the object.

4. The magnetic effects sensor according to claim 1, wherein discriminating the object includes determining whether the object detected meets a parameter of known threat of the object.

5. The magnetic effects sensor according to claim 1, the circuit is a nulled AC reactance bridge circuit across a predetermined frequency range that exploits impedance dependence to sense and discriminate the object presented to the coil from a bridge imbalance signal.

6. A precision variable resistor, comprising:
a converter configured to selectively convert information of a measured resistance due to a voltage drop pertaining to a current source;
a microprocessor receiving information of the measured resistance; and
a controller to sympathetic control resistance of an in-loop photoresistor with an out-loop photoresistor that are located parallel to each other.

7. The precision variable resister according to claim 6, wherein the controller is implemented via an optical control to maintain resistance of each photoresistor at a predetermined value.

8. A method of sensing, comprising:
sensing, using a magnetic effects sensor, inductance and resistance of an electrical coil; and
detecting an object based on a change of the inductance and the resistance of the electronic coil when the object is presented to the electronic coil.

9. The method according to claim 8, wherein the change in the inductance and resistance of the electronic coil is separated using a signal processing.

10. The method according to claim 8, wherein the object detected is formed of one of plastics and nonconductive ceramics.

11. The method according to claim 8, comprising:
sensing permeability and resistivity of the object.

12. The method according to claim 8, wherein said sensing is implemented to operate over various frequencies.
